(19) United States
(12) Patent Application Publication
(10) Pub. No.: US 2026/0268057 A1
(43) Pub. Date: Sep. 10, 2026

(54) FUNCTIONAL MODEL RECOVERY FROM TRANSISTOR NETWORKS FOR UNKNOWN CELL IDENTIFICATION

(71) Applicant: Battelle Memorial Institute, Columbus, OH (US)

(72) Inventors: Noah TAYLOR, Columbus, OH (US); Timothy A. MCDONLEY, Grove City, OH (US); Josh DELOZIER, Columbus, OH (US); Adam Gakuto KIMURA, Lewis Center, OH (US); Katie T. LISZEWSKI, Columbus, OH (US)

(21) Appl. No.: 19/221,702

(22) Filed: May 29, 2025

Related U.S. Application Data
(60) Provisional application No. 63/658,933, filed on Jun. 12, 2024.

(51) Int. Cl. G06F 30/392; G06F 30/323

(52) U.S. Cl. CPC G06F 30/392; G06F 30/323

(57) ABSTRACT

In an approach to functional model recovery from a transistor network for unknown cell identification, a method includes: determining a collection of logical equations from a layout of the transistor network; determining all valid internal states of the transistor network; for each of the valid internal states of the transistor network, determining an internal state of the transistor network after switching each input of one or more inputs of the transistor network; and constructing a Verilog module based on the internal state for each of the valid internal states of the transistor network.

### CROSS-REFERENCE TO RELATED APPLICATIONS

The present application claims the benefit of the filing date of U.S. Provisional Application Serial No. 63/658,933, filed Jun. 12, 2024, the entire teachings of which application is hereby incorporated herein by reference.

### STATEMENT REGARDING FEDERALLY SPONSORED RESEARCH OR DEVELOPMENT

This invention was made with government support under contract number FA8650-23-C-1000 awarded by the Air Force Research Laboratory. The government has certain rights in the invention.

### TECHNICAL FIELD

The present application relates generally to integrated circuit verification and, more particularly, to functional model recovery from transistor networks for unknown cell identification.

### BACKGROUND

Over the past few decades, as integrated circuits (ICs) have become more complex, the fabrication process has evolved into using smaller process nodes with more transistors. Economics and time-to-market pressures have driven manufacturing operations to offshore foundries along with the use/reuse of more third-party intellectual property (IP). These processes reduce visibility into the manufacturing supply chain and result in unknown assurance of the design. An important step to recapturing trust in the design is the decomposition and recovery of the fabricated chip, and subsequent verification and validation of the recovered design logic.

Standard cell libraries are critical components for driving the netlist recovery process. In some cases, the standard cell information needed for verification and validation of the recovered design logic may not be available due to, for example, IP sharing restrictions, data rights issues, or missing design information from obsolescence scenarios. Therefore, the design being verified may not have any standard cell library available, and an alternative workaround process must be explored. Verification in these circumstances involves recovering the cells by evaluating their transistor networks and compiling their operations into human-readable logical descriptions.

### BRIEF DESCRIPTION OF THE DRAWINGS

Reference should be made to the following detailed description which should be read in conjunction with the following figures, wherein like numerals represent like parts.

FIG. 1 illustrates a system for functional model recovery from transistor networks for unknown cell identification, consistent with the present disclosure.

FIG. 2 is an example of a transistor network to Verilog module flow for functional model recovery from transistor networks for unknown cell identification, consistent with the present disclosure.

FIG. 3A is an example open-source standard cell transistor network.

FIG. 3B is an example of a comparison between a constructed Verilog code module and the actual Verilog code module for the example of FIG. 3A.

FIG. 4A is an example open-source standard cell circuit schematic containing a mixture of combinational and sequential logic.

FIG. 4B is an example of a transistor schematic graph for the network of FIG. 4A.

FIG. 4C is an example of the extracted Verilog code from the network of FIG. 4A.

FIG. 5 is an example flow diagram for functional model recovery from sequential transistor networks for unknown cell identification, consistent with the present disclosure.

FIG. 6 is a detail of the example flow diagram of FIG. 5 illustrating the conversion of a layout into Boolean expressions, consistent with the present disclosure.

FIG. 7 is a detail of the example flow diagram of FIG. 5 illustrating the formation of a transition table, consistent with the present disclosure.

FIG. 8 is a detail of the example flow diagram of FIG. 5 illustrating the simplification of the transition table into a collapsed table, consistent with the present disclosure.

FIG. 9 is a detail of the example flow diagram of FIG. 5 illustrating the determination of edge sensitivity, consistent with the present disclosure.

FIG. 10 is a detail of the example flow diagram of FIG. 5 illustrating identifying the physically impossible output transitions, consistent with the present disclosure.

FIG. 11 is a detail of the example flow diagram of FIG. 5 illustrating combining rows to determine any inputs that do not affect the output transition, consistent with the present disclosure.

FIG. 12 is a detail of the example flow diagram of FIG. 5 further illustrating combining rows to determine any inputs that do not affect the output transition, consistent with the present disclosure.

FIG. 13 is a detail of the example flow diagram of FIG. 5 illustrating removing rows from the table that do not affect the output transition, consistent with the present disclosure.

FIG. 14 is a flowchart diagram depicting operations for functional model recovery from transistor networks for unknown cell identification, consistent with the present disclosure.

### DETAILED DESCRIPTION

Post-silicon design recovery and validation requires that the functional behavior of the design be recovered. If a design reference is not available or the process design kit (PDK) used is unknown, the functional behavior of partitions of the design must be determined. These partitions may be standard cells or groups of standard cells. There exists a need to recover functional models from transistor networks for unknown cell identification.

Disclosed herein is a system and method for functional model recovery from transistor networks for unknown cell identification. The disclosed system and method converts a digital MOSFET transistor network into a combinational or sequential Verilog module. In the disclosed system and method, a transistor schematic of each design subcircuit is transformed into a system of Boolean functions. These functions are developed by replacing all transistors with an ideal switching model. The subcircuits may represent standard cells or small groups of standard cells. The disclosed system and method allows for the simplification of the transition table and the extraction of simplified, human-readable Verilog from the system of Boolean functions.

The disclosed system and method requires no design reference or prior knowledge to extract simplified Verilog from a transistor schematic. Many common techniques involve some measure of comparison or template matching to provided references for known standard cells present in the design. The disclosed method can be applied even when individual standard cells are not reliably known. The method is suitable for transistor schematics resulting in sequential, and mixed combinational-sequential Boolean logic. The technique has been shown to simplify small groups of standard cells, relaxing the need to perfectly isolate all standard cells in a design with no reference.

Transistors are modeled as Boolean functions using idealized switching behavior. A transistor schematic is then modeled as a system of numerous Boolean functions. These schematics may represent combinational or sequential circuits.

If the outputs are combinationally dependent on the inputs (i.e., for each vector of inputs, there is only one possible value for each output), then an algorithm such as Quine-McCluskey can reduce the value of each output pin to a single logical expression, and the Verilog can be written out quite easily. The Quine-McCluskey algorithm is a method for simplification of combinational Boolean functions into those functions using only prime implicants, where a prime implicant is a product term that cannot be combined with another term to eliminate a variable. The algorithm need only worry about conditions for the output to be high.

If, however, one or more outputs are not purely dependent on the current values of the input pins, the network depends also on the previous values of the inputs and output. For these sequential Boolean functions, both high and low output states need to be considered. The system and method disclosed herein allows for the simplification of Boolean functions extracted from transistor schematics representing sequential circuits.

In some embodiments, the system and method disclosed herein may be implemented in three functional blocks. These blocks may include preliminary state analysis, where the values of each net at every allowable state of the design are determined; state transition analysis, where each input is inverted in turn at each state and the effects on the internal nets and the output are emulated and observed; and the actual Verilog construction, where the output is a fully descriptive module capturing the operation of the network.

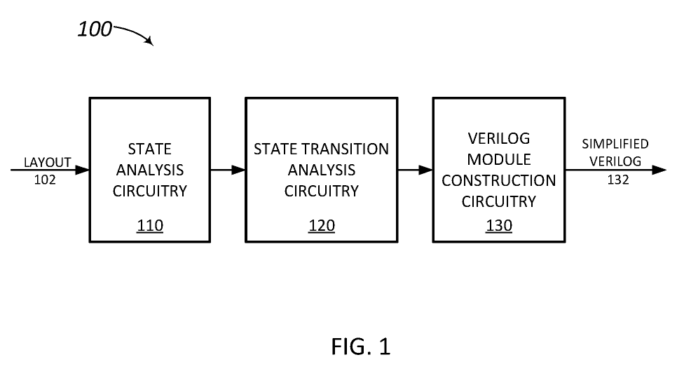

FIG. 1 illustrates a system 100 for functional model recovery from transistor networks for unknown cell identification, consistent with the present disclosure. The system 100 includes state analysis circuitry 110, which receives a layout 102 for a device. The state analysis circuitry 110 determines a set of logical equations that the nets must satisfy. The system 100 also includes state transition analysis circuitry 120, which determines the internal state after switching each of the inputs for each of the valid internal states of the network, and Verilog module construction circuitry 130, which performs the actual construction of the simplified Verilog 132, which is the output of the Verilog module construction circuitry 130.

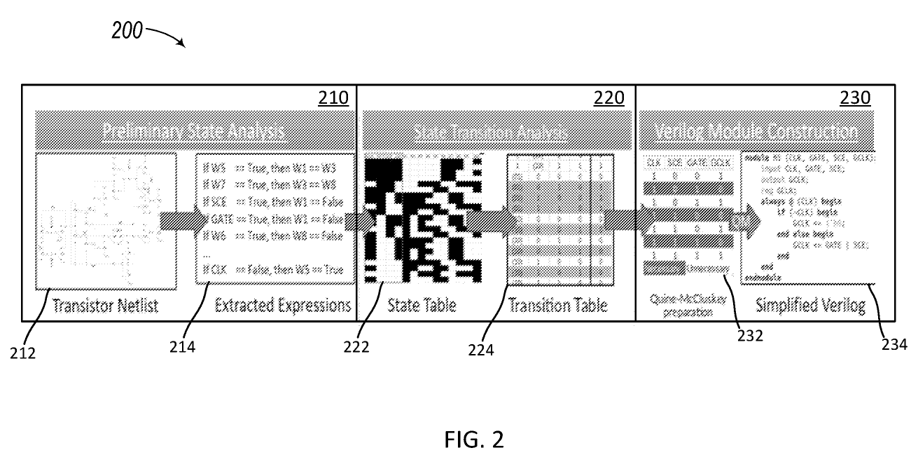

FIG. 2 is an example of a transistor network to Verilog module flow 200 for functional model recovery from transistor networks for unknown cell identification. The module flow 200 of FIG. 2 may be implemented, for example, on the system 100 of FIG. 1. The module flow 200 is divided into three blocks, a preliminary state analysis block 210, a state transition analysis block 220, and a Verilog module construction block 230.

In the preliminary state analysis block 210, a set of logical equations that the nets must satisfy is determined, and subsequently all possible states of the network are computed. For any transistor, when its gate pin receives a sufficient voltage so that the transistor enters saturation, it acts as a short between the source and drain pins. Therefore, each transistor in a transistor netlist 212 is converted into a logic statement of the form ‘If GATE == True, then SOURCE == DRAIN’ for n-channel metal-oxide semiconductors (NMOS) nodes, and a similar statement with opposite GATE condition for p-channel metal–oxide–semiconductor (PMOS) nodes. These logic statement may be fed into a Boolean satisfiability (SAT) solver to determine the possible values of each wire, and hence the output pins, at each value of the input pins. These results are shown in extracted expressions 214. As previously mentioned, if the outputs are combinationally dependent on the inputs then an algorithm such as Quine-McCluskey may be used to reduce the value of each output pin to a single logical expression. For sequential Boolean functions, the next block is used to analyze the transitions.

Next, for each valid internal state of the network in state table 222, the state transition analysis block 220 determines the internal state after switching each of the inputs. To do so, the state transition analysis block 220 emulates the execution of true transistors by propagating the transition outward and checking each new transistor. At each transistor, if the source or drain nodes update, and the gate is open, the opposite node also updates; if the gate is closed, then nothing happens. If instead, the gate switch is flipped, then the driven-ness (i.e., the existence or lack thereof of an open-gate path from either side to power or ground) is considered.

To understand a transistor once its gate pin is updated, a few simple rules may be followed. First, if a gate opens up, and one side is driven and the other is not, then the value of the second wire is updated to equal the first (as opposed to the possibility of updating the other way around). Second, if a gate opens up and neither side is driven, the other transistors that also need to be updated are inspected with higher priority. If the value on one of the sides of the transistor eventually becomes driven, then the other side is simultaneously updated. Otherwise, neither side is ever driven; but well-formed transistor networks that are not tri-state must have outputs that are driven, so the value of the undriven net is unimportant.

Each transition for each state is computed and combined into a transition table 224. Then the transitions where the outputs switch are noted and will appear in the sensitivity list of the Verilog always block.

Finally, the Verilog module construction block 230 performs the actual construction of the simplified Verilog 234. In a Verilog always block, the output value and sensitivity list are independent, and as the sensitivity list has been constructed, the output value is constructed. Each line in which at least one of transition sensitivity condition is met is collected into a table 232, noting the end result of each input, the original value of the output, and the new output. That is, once the transition lines have been determined, the previous state of the inputs is ignored. Additionally, all remaining combinations of input values and original output values are added to the table 232 twice, with both high and low values for the final output state. The purpose of these lines are for simplification of the output value. Finally, the Quine-McCluskey algorithm can be used to reduce the output to a single logical expression. An important component of the Quine-McCluskey algorithm is the ability to handle don’t-care lines, and the spurious lines appended to the end form the set of don’t-care lines for Quine-McCluskey algorithm. The actual disjunctive terms may be converted to a standard Verilog style, e.g., instead of writing ‘Q <= (SET) | (D),’ the expression may be split into an if-else block, but the formula is complete as written.

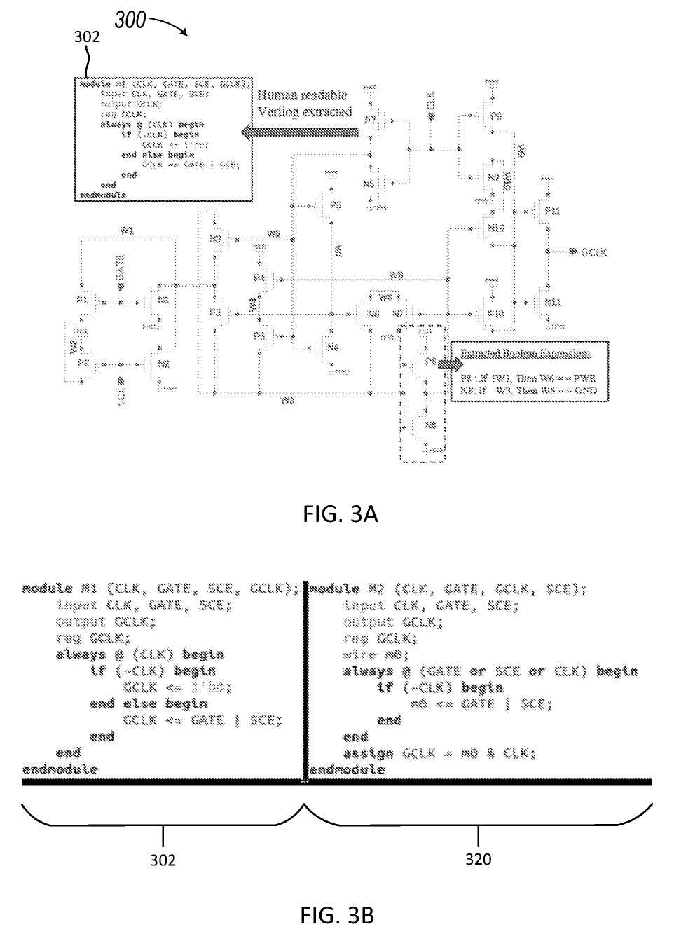

FIG. 3A is an example open-source standard cell transistor network 300. The example standard cell transistor network 300 of FIG. 3A was created from a scan gated clock cell from an open-source foundry PDK. In the example of FIGS. 3A and 3B, the PDK used was the SkyWater 130 nm PDK from SkyWater Technology and the scan gated clock cell was the sdlclkp_1. In this example there are 11 PMOS transistors, 11NMOS transistors, 10non-I/O nets, 3input pins, and 1 output pin. The 22possible states are found in the state table 222 of FIG. 2, where the first four columns outlined in red represent the values of the output GCLK and the inputs GATE, SCE and CLK. Because all of the inputs remain on but GCLK varies in the last four lines, this represents a sequential, not combinational, network. Next, the set of transitions are calculated from each of these 22 states. All transitions with the same first four columns have the same new GCLK, (i.e., none of the internal wires are important), so the transition table 224 depends only on the inputs and output. It ends up being 36lines, a selection of which are depicted in the transition table 224 of FIG. 2, as there are three possible transitions from each state, one for each input, and there are 12 distinct possible IO vectors. The transition lines end up being only when CLK switches from False to True or vice versa.

Therefore, the always condition becomes ‘always @ (CLK).’ The 12 transition lines depending on CLK are pulled from the transition table 224, and 8 more lines are added because GCLK can never start as high when CLK transitions from low to high. These 20 lines are analyzed with the Quine-McCluskey algorithm, and the new output, GCLK+, is equal to ‘(CLK & GATE) | (CLK & SCE)’. The final generated Verilog output 302 as well as the Verilog provided by SkyWater 320 are shown in FIG. 3B for comparison.

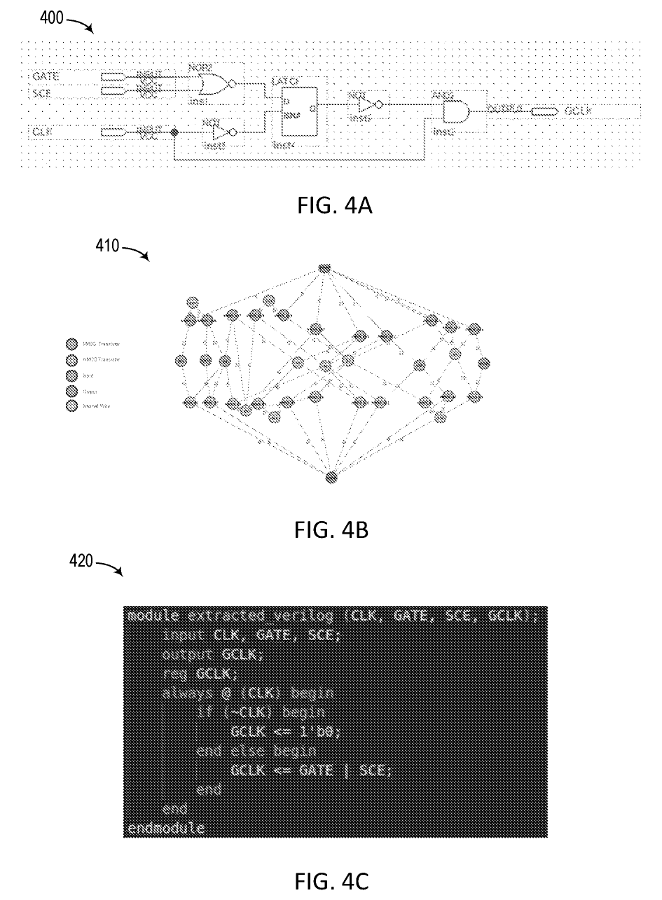

FIGS. 4A – 4C illustrate an example test case for a transistor network with multiple standard cells. FIG. 4A is an example open-source standard cell circuit schematic 400 containing a mixture of combinational and sequential logic. FIG. 4B is an example of a graphical representation 410 of the transistor schematic for the standard cell circuit schematic 400 of FIG. 4A. FIG. 4C is an example of the extracted Verilog code 420 from the graphical representation 410 of FIG. 4B.

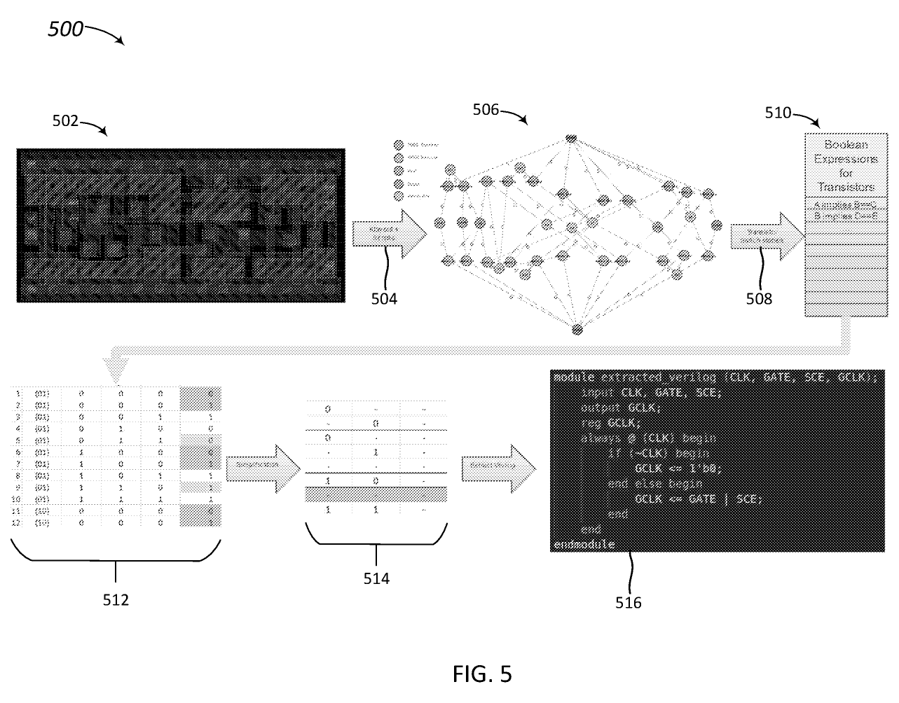

FIG. 5 is an example flow diagram 500 for functional model recovery from sequential transistor networks for unknown cell identification, consistent with the present disclosure. The example flow diagram includes a subcircuit 502 extracted from a layout. The subcircuit 502 may contain, for example, a standard cell or a group of standard cells. The subcircuit 502 is converted into a graphical representation 506 of the transistor schematic. The subcircuit 502 may be converted into the graphical representation 506 by use of standard tools, for example, computer-aided design (CAD) tools 504, such as the open-source Klayout, and custom scripts. Transistor switch models 508 are then used to generate a set of Boolean expressions 510 for the transistor network. State transitions, shown in the transition table 512, are generated from the set of Boolean expressions 510, which are then simplified as shown in simplified table 514. Finally, the Verilog module 516 is extracted.

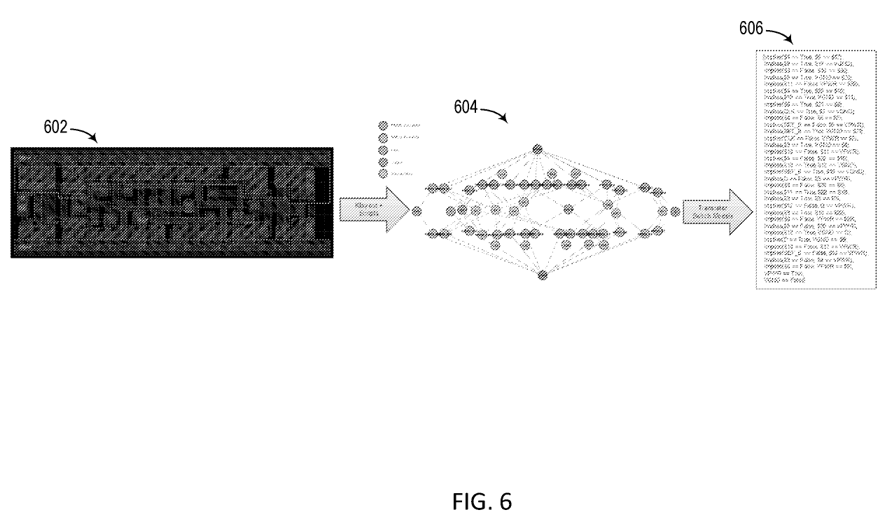

The operations of the example flow diagram of FIG. 5 are explained in greater detail in FIGS. 6-13 below. FIGS. 6-13 includes an example standard cell layout 602 (FIG. 6) which, in this example, is a standard cell for a flip flop (sky130_fd_sc_hd__dfstp_1 ) from the SKY130, 130nm PDK from SkyWater Technology. It should be noted that this standard cell is used for illustrative purposes only. Any other standard cell or group of standard cells could be used following the operations of FIG. 5.

FIG. 6 illustrates the conversion of a layout into Boolean expressions. In FIG. 6, the standard cell layout 602 is converted to a graphical representation 604. Inputs, outputs, internal nets, and transistors may be automatically identified without labels or references. Transistor switch models are used to generate a set of Boolean expressions 606 for the transistors from the graphical representation 604. The transistor switch models may be, for example, switch models that are idealized using the Z3 satisfiability modulo theories (SMT) solver from Microsoft Research.

In this example, the Z3 SMT solver is used to evaluate and generate the states. It should be noted, however, that many other methods may be used to evaluate and generate the states, as would be known by a person of skill in the art.

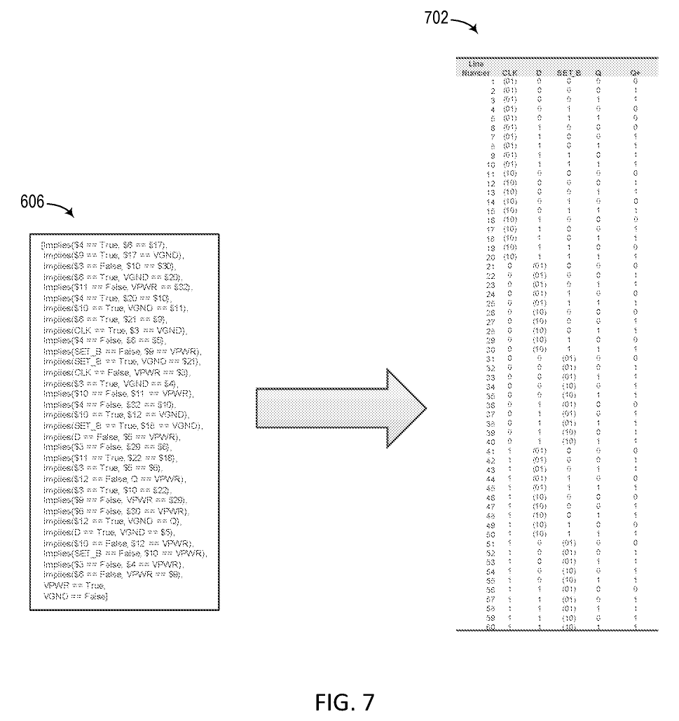

FIG. 7 illustrates the formation of a transition table 702. The states in transition table 702 are formed through analysis of the Boolean expressions 606. Each line of the transition table 702 has one input transition, either low to high (01) or high to low (10). Q is the output and Q+ is the state of the output after the transition. CLK, D, SET_B are inputs whose function is not known.

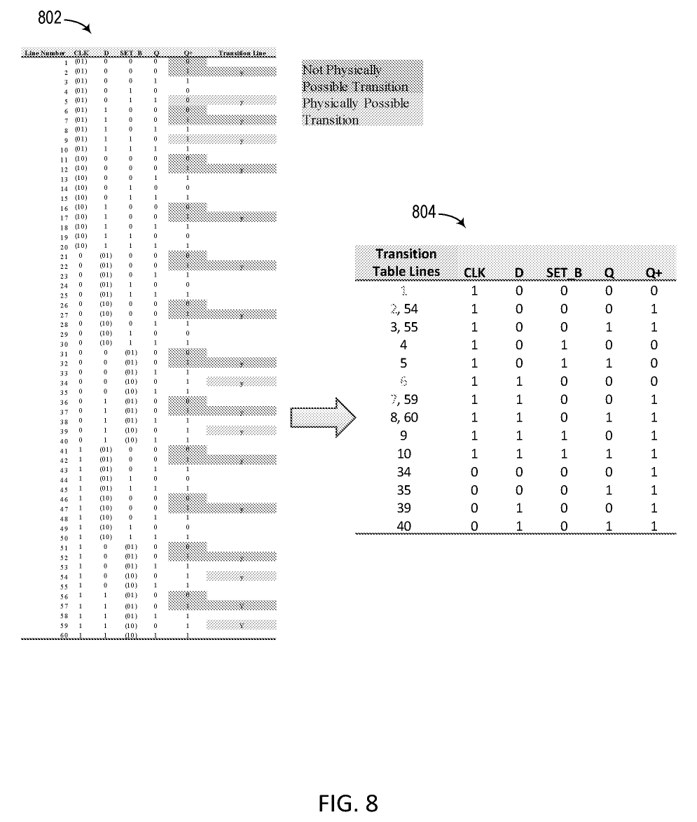

FIG. 8 illustrates the simplification of the transition table into a collapsed table. In FIG. 8, the marked transition table 802 starts as the transition table 702 from FIG. 7. First the lines where an input transition causes an output transition are marked, i.e., an output transition occurs when Q is not equal to Q+. Each output transition is marked as being physically possible or not physically possible, where a state is not physically possible if there is no electrical connection possible to drive the state of Q+ after the input transition.

CLK and SET_B both have at least one transition that causes a physically possible output transition. All lines with a transition for CLK or SET_B are moved into a collapsed table 804. The second state in each input transition is recorded to the collapsed table 804.

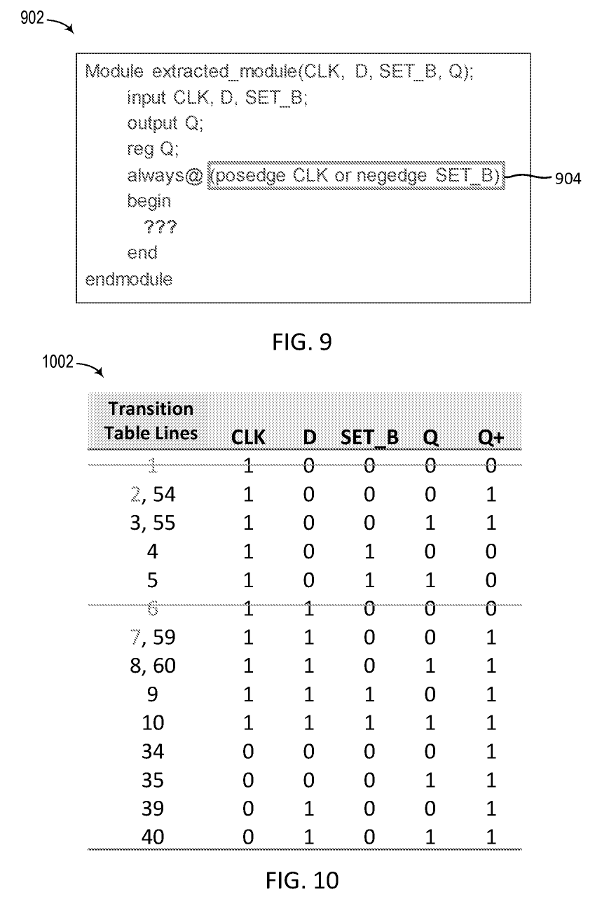

FIG. 9 illustrates the determination of edge sensitivity. In extracted module 902, CLK and SET_B both have at least one transition that causes a physically possible output transition. CLK is posedge sensitivity (the transition from 0 to 1) and SET_B is negedge sensitivity (the transition from 1 to 0), as shown by box 904.

In FIG. 10, the collapsed table 804 keeps track of which row(s) from the full table they represent. Rows in the collapsed table 804 that only have red line numbers are thrown out. If the row had a physically impossible output transition it is marked red in an updated collapsed table 1002. In this example, row 1 and row 6 in the updated collapsed table 1002 only have red line numbers and are therefore thrown out.

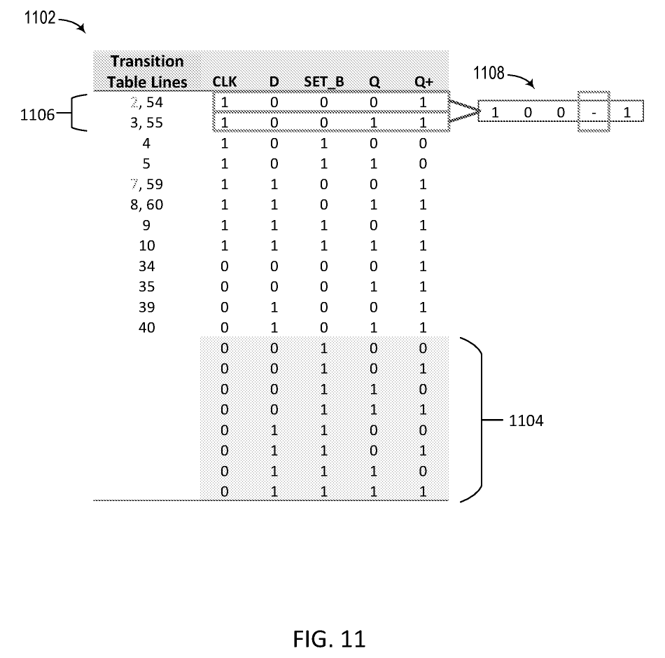

FIG. 11 illustrates combining rows to determine any inputs that do not affect the output transition. The rows 1104 shaded yellow in collapsed table 1102 are added to prevent over constraining the simplified solution. The rows are produced by including all possible combinations of values after the identified inputs are held to their initial value, i.e., CLK = 0 and SET_B = 1. Rows are then combined to determine any inputs that do not affect the output transition. As an example, the first two rows 1106 can be combined to show that Q+ does not depend on Q in that instance. As can be seen in the first two rows 1106, Q has values of both 0 (first row) and 1 (second row), and therefore Q+ does not depend on Q. The result is combined row 1108, which is the combination of the first two rows 1106.

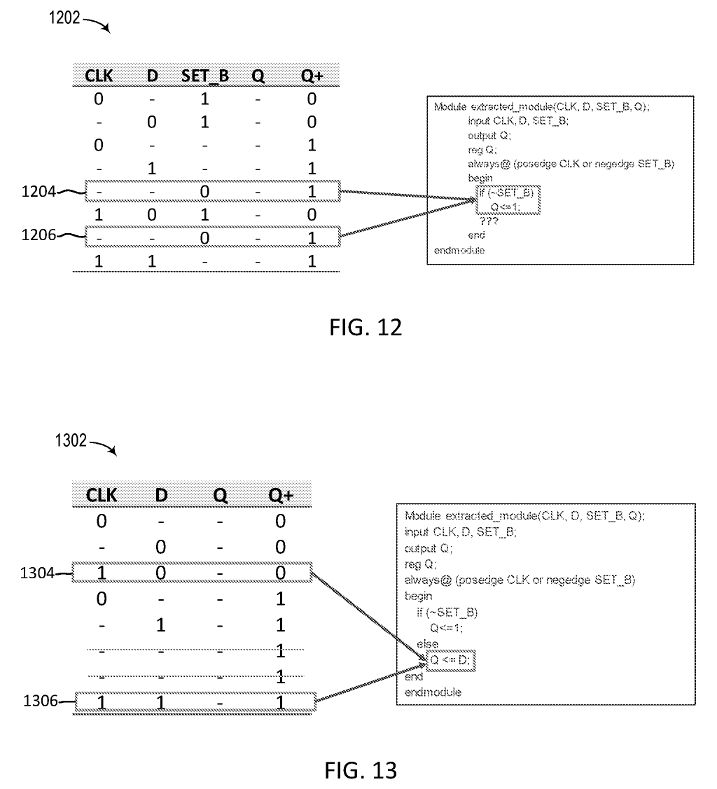

FIG. 12 further illustrates combining rows to determine any inputs that do not affect the output transition. The process is repeated until no more lines can be merged. SET_B is clearly a negedge set, and the previous steps identified SET_B (10) as an important transition. Here, the lines 1204 and 1206 in this table 1202 show Q+ only depends on SET_B when it is low. In FIG. 13, therefore, SET_B is removed from the table. Next, lines with only '–' (don't care) for inputs or Q are removed. In this example, line 1304 and line 1306 both have '–' for Q, so both of these lines are removed. CLK is the only transition input left and is identified as a posedge clock. Finally, the remainder of the table is simplified down to a combinational statement for the else block.

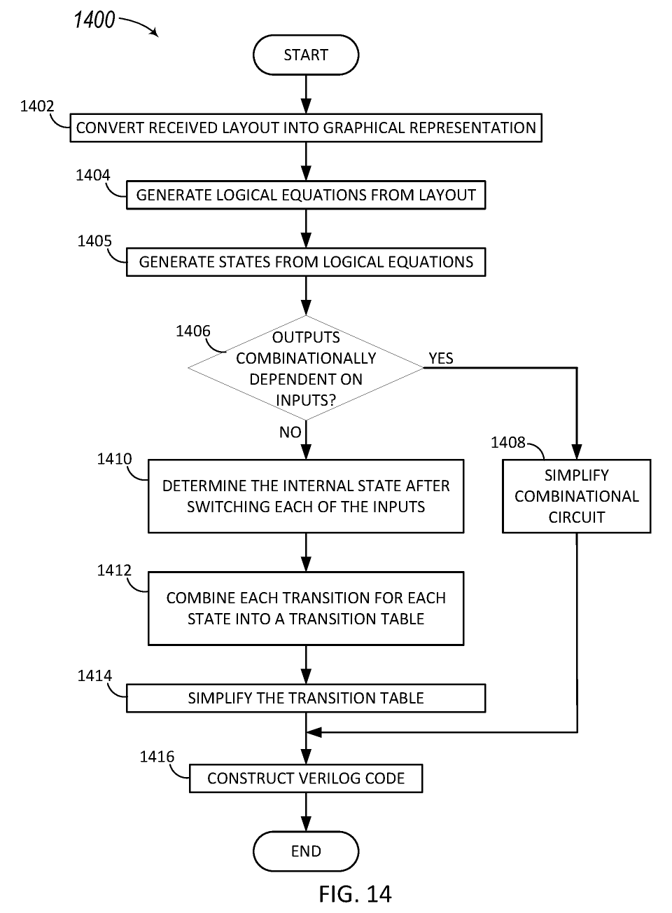

FIG. 14 is a flowchart diagram depicting operations for an illustrative example embodiment of a method 1400 for functional model recovery from transistor networks for unknown cell identification, consistent with the present disclosure. It should be appreciated that embodiments of the present disclosure provide at least for functional model recovery from transistor networks for unknown cell identification. However, FIG. 14 provides only an illustration of one implementation and does not imply any limitations with regard to the environments in which different embodiments may be implemented. Many modifications to the depicted environment may be made by those skilled in the art without departing from the scope of the disclosure as recited by the claims.

Convert received layout into graphical representation (operation 1402). In the illustrated example embodiment, one or more layouts are received for each design subcircuit of the part to be processed. The layout may be, for example, a group of standard cells comprising combinational circuits, sequential circuits, or a mix of combinational and sequential circuits. The layout is then converted into a graphical representation of a transistor schematic. Inputs, outputs, internal nets, and transistors may be automatically identified without labels or references.

Generate logical equations from the layout (operation 1404). In this operation, the graphical representation of the standard cell layout is converted into a set of logical equations, i.e., Boolean expressions, of a transistor schematic. Transistor switch models may be used to generate the Boolean expressions for the transistors from the graphical representation.

Generate states from the logical equations (operation 1405). In this operation, the states are formed through analysis of the Boolean expressions generated in operation 1404. In some embodiments, the Z3 SMT solver may be used to evaluate and generate the states. In some other embodiments, any other method may be used to evaluate and generate the states, as would be known by a person of skill in the art. The results of operation 1405 is a list of the states determined from the logical equations.

Outputs combinationally dependent on inputs? (decision block 1406). Whether the outputs combinationally dependent on inputs, i.e., whether the circuit is combinational and not sequential is determined. If the outputs are combinationally dependent on inputs (“yes” branch, decision block 1406), then method 1400 proceeds to operation 1408 to process the combinational circuit. If the outputs are not combinationally dependent on inputs, i.e., the circuit is sequential (“no” branch, decision block 1406), then method 1400 proceeds to operation 1410.

Simplify combinational circuit (operation 1408). If it is determined in decision block 1406 that the outputs are only combinationally dependent on the inputs, then the system may obtain formulas for combinational circuits directly. When the outputs are only combinationally dependent on the inputs, then the system only has to address conditions for the output to be high. In some embodiments, a method for simplification of combinational Boolean functions into those functions using only prime implicants, such as the Quine-McCluskey algorithm, may be used. The method 1400 then proceeds to operation 1416.

Determine the internal state after switching each of the inputs (operation 1410). If it is determined in decision block 1406 that the outputs are not only combinationally dependent on the inputs, i.e., the circuit is sequential, then the system determines the internal state after switching each of the inputs.

Combine each transition for each state into a transition table (operation 1412). Each line of the transition table has one input transition, either low to high or high to low. For each valid internal state of the network determined in operation 1410, the internal state is determined after switching each of the inputs. To do so, the execution of true transistors is emulated by propagating the transition outward and checking each new transistor. At each transistor, if the source or drain nodes update, and the gate is open, the opposite node also updates; if the gate is closed, then nothing happens. If instead, the gate switch is flipped, then the driven-ness (i.e., the existence or lack thereof of an open-gate path from either side to power or ground) is considered.

To understand a transistor once its gate pin is updated, a few simple rules may be followed. First, if a gate opens up, and one side is driven and the other is not, then the value of the second wire is updated to equal the first (as opposed to the possibility of updating the other way around). Second, if a gate opens up and neither side is driven, the other transistors that also need to be updated are inspected with higher priority. If the value on one of the sides of the transistor eventually becomes driven, then the other side is simultaneously updated. Otherwise, neither side is ever driven; but well-formed transistor networks that are not tri-state must have outputs that are driven, so the value of the undriven net is unimportant. Each transition for each state is computed and combined into a transition table. Then the transitions where the outputs switch are noted and will appear in the sensitivity list of the Verilog always block.

Simplify the transition table (operation 1414). In operation 1414, the transition table is simplified into a collapsed table. In an embodiment, the lines where the input transition causes an output transition are marked, and each output transition is marked as being physically possible or not physically possible. All lines marked as being physically possible are moved into a collapsed transition table. The second state in each input transition is recorded to the collapsed table. Next, the edge sensitivity is determined for each line in the collapsed transition table. For any row in the collapsed table has a physically impossible output transition, it is marked red in an updated collapsed table. Rows are then combined to determine any inputs that do not affect the output transition. The process is repeated until no more lines can be merged. Next, lines with only '–' (don't care) for inputs or outputs are removed.

Construct Verilog code (operation 1416). Once the collapsed transition table has been fully reduced, the remaining expressions from the transition table, and the reduced expressions for the combinational circuits from operation 1408, are converted into Verilog modules.

According to one aspect of the disclosure there is thus provided a method for functional model recovery from a transistor network for unknown cell identification. The method includes: determining a collection of logical equations from a layout of the transistor network; determining all valid internal states of the transistor network; for each of the valid internal states of the transistor network, determining an internal state of the transistor network after switching each input of one or more inputs of the transistor network; and constructing a Verilog module based on the internal state for each of the valid internal states of the transistor network.

According to another aspect of the disclosure, there is thus provided a system for functional model recovery from a transistor network for unknown cell identification. The system includes: state analysis circuitry; state transition analysis circuitry; Verilog module construction circuitry. The system is configured to: determine a collection of logical equations from a layout of the transistor network; determine all valid internal states of the transistor network; for each of the valid internal states of the transistor network, determine an internal state of the transistor network after switching each input of one or more inputs of the transistor network; and construct a Verilog module based on the internal state for each of the valid internal states of the transistor network.

As used in this application and in the claims, a list of items joined by the term “and/or” can mean any combination of the listed items. For example, the phrase “A, B and/or C” can mean A; B; C; A and B; A and C; B and C; or A, B and C. As used in this application and in the claims, a list of items joined by the term “at least one of” can mean any combination of the listed terms. For example, the phrases “at least one of A, B or C” can mean A; B; C; A and B; A and C; B and C; or A, B and C.

The term “coupled" as used herein refers to any connection, coupling, link, or the like by which signals carried by one system element are imparted to the "coupled" element. Such “coupled" devices, or signals and devices, are not necessarily directly connected to one another and may be separated by intermediate components or devices that may manipulate or modify such signals.

Unless otherwise stated, use of the word "substantially" may be construed to include a precise relationship, condition, arrangement, orientation, and/or other characteristic, and deviations thereof as understood by one of ordinary skill in the art, to the extent that such deviations do not materially affect the disclosed methods and systems. Throughout the entirety of the present disclosure, use of the articles "a" and/or "an" and/or "the" to modify a noun may be understood to be used for convenience and to include one, or more than one, of the modified noun, unless otherwise specifically stated. The terms "comprising", "including" and "having" are intended to be inclusive and mean that there may be additional elements other than the listed elements.

Any of the operations described herein may be implemented in a system that includes one or more non-transitory storage devices having stored therein, individually or in combination, instructions that when executed by circuitry perform the operations. “Circuitry”, as used in any embodiment herein, may comprise, for example, singly or in any combination, hardwired circuitry, programmable circuitry such as processors comprising one or more individual instruction processing cores, state machine circuitry, and/or firmware that stores instructions executed by programmable circuitry and/or future computing circuitry including, for example, massive parallelism, analog or quantum computing, hardware embodiments of accelerators such as neural net processors and non-silicon implementations of the above. The circuitry may, collectively or individually, be embodied as circuitry that forms part of a larger system, for example, an integrated circuit (IC), system on-chip (SoC), application-specific integrated circuit (ASIC), programmable logic devices (PLD), digital signal processors (DSP), field programmable gate array (FPGA), logic gates, registers, semiconductor device, chips, microchips, chip sets, etc.

The storage device includes any type of tangible medium, for example, any type of disk including hard disks, floppy disks, optical disks, compact disk read-only memories (CD-ROMs), compact disk rewritables (CD-RWs), and magneto-optical disks, semiconductor devices such as read-only memories (ROMs), random access memories (RAMs) such as dynamic and static RAMs, erasable programmable read-only memories (EPROMs), electrically erasable programmable read-only memories (EEPROMs), flash memories, Solid State Disks (SSDs), embedded multimedia cards (eMMCs), secure digital input/output (SDIO) cards, magnetic or optical cards, or any type of media suitable for storing electronic instructions. Other embodiments may be implemented as software executed by a programmable control device. Also, it is intended that operations described herein may be distributed across a plurality of physical devices, such as processing structures at more than one different physical location.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents. Various features, aspects, and embodiments have been described herein. The features, aspects, and embodiments are susceptible to combination with one another as well as to variation and modification, as will be understood by those having skill in the art. The present disclosure should, therefore, be considered to encompass such combinations, variations, and modifications.

Reference throughout this specification to “one embodiment” or “an embodiment” means that a particular feature, structure, or characteristic described in connection with the embodiment is included in at least one embodiment. Thus, appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

What is claimed is:

1. A method for functional model recovery from a transistor network for unknown cell identification, the method comprising:
determining a collection of logical equations from a layout of the transistor network;
determining all valid internal states of the transistor network;
for each of the valid internal states of the transistor network, determining an internal state of the transistor network after switching each input of one or more inputs of the transistor network; and
constructing a Verilog module based on the internal state for each of the valid internal states of the transistor network.

2. The method of claim 1, wherein determining the collection of the logical equations from the layout of the transistor network further comprises:
replacing each transistor of a plurality of transistors in the transistor network with an ideal switching model.

3. The method of claim 1, wherein for each of the valid internal states of the transistor network, determining the internal state of the transistor network after switching each input of the one or more inputs of the transistor network further comprises:
responsive to determining that one or more outputs of the transistor network are combinationally dependent on the one or more inputs of the transistor network, reducing a value of each output of one or more outputs from the transistor network to a single logical expression.

4. The method of claim 3, wherein for each of the valid internal states of the transistor network, determining the internal state of the transistor network after switching each input of the one or more inputs of the transistor network further comprises:
combining the internal state for each of the valid internal states of the transistor network after switching each input of the one or more inputs of the transistor network into a transition in a transition table; and
responsive to the transition having any output of the one or more outputs switch, adding the transition to an always block in the Verilog module.

5. The method of claim 4, wherein constructing the Verilog module based on the internal state for each of the valid internal states of the transistor network further comprises:
collecting each transition in the transition table where a transition sensitivity condition is met; and
reducing the transition table to the single logical expression.

6. The method of claim 5, wherein reducing the transition table to the single logical expression uses a Quine-McCluskey algorithm.

7. A system for functional model recovery from a transistor network for unknown cell identification, the system comprising:
state analysis circuitry;
state transition analysis circuitry;
Verilog module construction circuitry; and
the system configured to:
determine a collection of logical equations from a layout of the transistor network;
determine all valid internal states of the transistor network;
for each of the valid internal states of the transistor network, determine an internal state of the transistor network after switching each input of one or more inputs of the transistor network; and
construct a Verilog module based on the internal state for each of the valid internal states of the transistor network.

8. The system of claim 7, wherein determine the collection of the logical equations from the layout of the transistor network further comprises:
replace each transistor of a plurality of transistors in the transistor network with an ideal switching model.

9. The system of claim 7, wherein for each of the valid internal states of the transistor network, determine the internal state of the transistor network after switching each input of the one or more inputs of the transistor network further comprises:
responsive to determining that one or more outputs of the transistor network are combinationally dependent on the one or more inputs of the transistor network, reduce a value of each output of one or more outputs from the transistor network to a single logical expression.

10. The system of claim 9, wherein for each of the valid internal states of the transistor network, determine the internal state of the transistor network after switching each input of the one or more inputs of the transistor network further comprises:
combine the internal state for each of the valid internal states of the transistor network after switching each input of the one or more inputs of the transistor network into a transition in a transition table; and
responsive to the transition having any output of the one or more outputs switch, add the transition to an always block in the Verilog module.

11. The system of claim 10, wherein construct the Verilog module based on the internal state for each of the valid internal states of the transistor network further comprises:
collect every line in the transition table where a transition sensitivity condition is met; and
reduce the transition table to the single logical expression.

12. The system of claim 11, wherein reduce the transition table to the single logical expression uses a Quine-McCluskey algorithm.

13. A method for functional model recovery from a transistor network for unknown cell identification, the method comprising:
receiving a layout of the transistor network;
converting the layout into a graphical representation of a transistor schematic;
determining Boolean expressions for each transistor of the transistor network;
determining one or more states from the Boolean expressions;
simplifying the one or more states; and
constructing a Verilog module based on one or more simplified states.

14. The method of claim 13, wherein determining the Boolean expressions for each transistor of the transistor network further comprises:
replacing each transistor of a plurality of transistors in the transistor network with an ideal switching model.

15. The method of claim 13, wherein determining the one or more states from the Boolean expressions further comprises:
inserting the one or more states into a transition table, wherein each line of the transition table has one input transition;
marking each line of the transition table where the input transition causes an output transition; and
marking each line of the transition table with the output transition as being physically possible or not physically possible.

16. The method of claim 15, further comprising:
responsive to the output transition for any Boolean expression being combinationally dependent on the input transition, simplify the Boolean expression as a combinational circuit.

17. The method of claim 15, wherein the output transition is not physically possible if there is no electrical connection to drive the output transition after the input transition.

18. The method of claim 17, wherein simplifying the one or more states further comprises:
inserting each line of the transition table where the input transition causes the output transition that is physically possible into a collapsed transition table;
inserting a second state for each input transition that causes the output transition that is physically possible into a line in the collapsed transition table;
determining an edge sensitivity for each line in the collapsed transition table; and
combining any lines in the collapsed transition table where any input does not affect the output transition.

19. The method of claim 18, further comprising:
removing any line of the transition table having only don’t care for inputs.

20. The method of claim 19, wherein the collapsed transition table is simplified to a combinational statement for a block of the Verilog module.
